(19) United States
(12) Patent Application Publication
(10) Pub. No.: US 2010/0044556 A1
(43) Pub. Date: Feb. 25, 2010

(54) OSCILLATING DEVICE AND LIGHT- DEFLECTION APPARATUS EMPLOYING THE SAME

(75) Inventor: Kazufumi Onuma, Tokyo (JP)

Correspondence Address: FITZPATRICK CELLA HARPER & SCINTO, 1290 Avenue of the Americas, NEW YORK, NY, 10104-3800, US

(73) Assignee: CANON KABUSHIKI KAISHA, Tokyo (JP)

(21) Appl. No.: 12/534,965

(22) Filed: Aug. 4, 2009

(30) Foreign Application Priority Data
Aug. 20, 2008 (JP) 2008-211608

(51) Int. Cl. H04N 1/047; H03L 7/00

(52) U.S. Cl. 250/235; 331/15

(57) ABSTRACT

A oscillating member device comprises: an oscillation system containing of a oscillating member and an elastic support, a driver unit for supplying a driving force to the oscillation system according to a driving signal, a waveform generator for generating periodic signals at a prescribed frequency, a driving signal generator for generating the driving signals in accordance with the periodic signals and an amplitude control level, and a oscillating amplitude detector for detecting a oscillating amplitude of the oscillating member; and practicing a control loop for controlling the amplitude control level according to a difference between a target oscillating amplitude and a detected oscillating amplitude detected by the oscillating amplitude detector, and the gain thereof; the oscillating member device comprising a gain adjuster for adjusting a gain of the control loop, and the gain of the gain adjuster being set based on the amplitude control level in a state that the oscillating amplitude of the oscillating member is equal to a target oscillating amplitude.

### BACKGROUND OF THE INVENTION

1. Field of the Invention

The present invention relates to a oscillating member device having a oscillating member supported to be swingable. More specifically, the present invention relates to a oscillating member device, a light-beam deflection apparatus employing the oscillating member, and a method of driving the oscillating member device by adjusting the control loop gain. The light deflection apparatus is useful as an optical instrument containing an imaging device such as a scanning type display, a laser beam printer, and digital copying machine.

2. Description of the Related Art

Conventional resonance type light deflection apparatuses are advantageous in comparison with optical scanning system employing a rotary polygonal mirror in that the size of the apparatus can be made smaller, the power consumption is less, and no mirror face fluctuation is caused theoretically. However, this resonance type light deflection apparatus is disadvantageous in that the oscillating amplitude is less stable due to disturbance by the air. A method is disclosed for canceling this disadvantage (Japanese Patent Application Laid-Open No. H05-45603).

Japanese Patent Application Laid-Open No. H05-45603 discloses a constitution of an oscillation system, wherein the time at which the scanning beam passes a certain scanning point or the time at which the scanning beam passes a certain deflection angle is measured by a means for detecting the position of the scanning beam deflected or scanned by the oscillating member or a means for detecting the deflecting angle of the oscillating member, and the oscillating movement of the oscillating member is controlled to be equal to a predetermined reference time.

On the other hand, U.S. Pat. No. 5,347,124 discloses control of driving signals of a light beam deflection device by a deflection angle, or the maximum thereof, of the reflection mirror of a light deflector. Specifically with this system, the variable resistance element constituting the differential circuit for the PID calculation is controlled for adjusting to be optimum the amplitude or oscillation state of the reflection mirror of the resonance type deflection.

U.S. Pat. No. 7,271,943 discloses a micro-oscillating member comprising torsion springs and movable elements having a plurality of isolated characteristic oscillation modes. In this micro-oscillating member, there exist a reference oscillation mode which is characteristic oscillation mode of a reference frequency, and an even-numbered oscillation mode which is a characteristic oscillation mode of a frequency oscillation being approximately even-number times the reference frequency. A saw-teeth wave drive is realized by oscillation of the micro-oscillating member.

However, resonance type light deflection apparatus has the driving sensitivity of the oscillation system (the ratio of the change of oscillating amplitude of the oscillating member to the change of amplitude control mentioned later) which can vary greatly owing to deviation between the resonance frequency and the drive frequency and variation in production of the oscillation system and the driving system. Such a great variation cannot readily be corrected by the control circuit for a fixed control loop gain.

In particular, in the resonance type light deflection apparatus having plural oscillating members as disclosed by the aforementioned U.S. Pat. No. 7,271,943, the ratio of the plural resonance frequencies in the oscillation system is not in an integer ratio due to variation in the production process, so that the resonance frequency and the driving frequency cannot readily be made to coincide with each other, and the variation of the driving sensitivity is considerable.

### SUMMARY OF THE INVENTION

The present invention is directed to a oscillating member device comprising: an oscillation system containing of a oscillating member and an elastic support, a driver unit for supplying a driving force to the oscillation system according to a driving signal, a waveform generator for generating periodic signals at a prescribed frequency, a driving signal generator for generating the driving signals in accordance with the periodic signals and an amplitude control level, and a oscillating amplitude detector for detecting a oscillating amplitude of the oscillating member; and practicing a control loop for controlling the amplitude control level according to a difference between a target oscillating amplitude and a detected oscillating amplitude detected by the oscillating amplitude detector, and the gain thereof; the oscillating member device further comprising a gain adjuster for adjusting a gain of the control loop, and the gain of the gain adjuster being set based on the amplitude control level in a state that the oscillating amplitude of the oscillating member is equal to a target oscillating amplitude.

In the oscillating member device, in practicing the control loop, the gain of the gain adjuster can be set in accordance with the amplitude control level in a state that the difference between the target oscillating amplitude and the detected oscillating amplitude detected by the oscillating amplitude detector comes to be within a predetermined range.

In the oscillating member device, wherein a control level memory can be provided for memorizing the amplitude control level, the amplitude control level in the state in which the oscillating amplitude of the oscillating member becomes equal to the target oscillating amplitude is memorized in the control memory at a first timing, and the gain is set in the gain adjuster according to the amplitude control level stored in the control level memory at a second timing.

In the oscillating member device, a gain memory can be provided for memorizing the gain to be set in the gain adjuster, a gain for the gain adjuster is derived according to the amplitude control level in the state that the oscillating amplitude of the oscillating member is nearly equal to the target oscillating amplitude, and the gain is memorized in a gain memory at a first timing; and the gain stored in the control level memory is set in the gain adjuster at a second timing.

In the oscillating member device, a filter can be provided for suppressing high-range variation of the amplitude control level, and the gain is set in the gain adjuster successively in accordance with the output of the filter.

In the oscillating member device, a conversion equation which converts the amplitude control level to the gain to be set in the gain adjuster and necessary for obtaining the target oscillating amplitude can be defined.

The oscillation system can have a plurality of oscillating members and a plurality of elastic supports; the resonance frequencies include a primary resonance frequency and a secondary resonance frequency of n-times the primary resonance frequency (n: an integer of 2 or more); the waveform generator outputs a fundamental periodic signal of the prescribed frequency and an n-th wave periodic signal of n-times the frequency of the prescribed frequency; the driving signal generator generates a fundamental wave driving signal based on the fundamental wave periodic signal and the fundamental wave amplitude control level, and generates also an n-th wave driving signal based on the n-th periodic signal and n-th wave amplitude control level; the driver unit supplies a driving force to the oscillation system based on the fundamental wave driving signal and the n-th wave driving signal; the oscillating amplitude detector detects oscillating amplitudes of the oscillation system corresponding to the fundamental wave driving signal and/or the n-th wave driving signal; the control loop of the control of the fundamental wave amplitude control level and/or the n-th wave amplitude control level is practiced based on the difference of the target oscillating amplitude and the detected oscillating amplitude detected by the oscillating amplitude detector and the fundamental wave control loop gain and/or the n-th wave control loop gain; the gain adjuster adjusts the fundamental wave control loop gain and/or the n-th wave control loop gain of the control loop; and the fundamental wave control loop gain and/or the n-th wave control loop gain are set in the gain adjuster based on the fundamental wave amplitude control level and/or the n-th wave amplitude control level in the state that the oscillating amplitude corresponding to the fundamental wave driving signal and/or the n-th wave control signal is nearly equal to the target oscillating amplitude.

The present invention is directed to a light deflection apparatus employing the oscillating member device, having an optical deflection element placed in at least one oscillating member for deflecting a light beam introduced to the optical deflection element.

The present invention is directed to an optical instrument, employing the light deflection apparatus, a light source, and a light irradiation object, which deflects a light beam emitted from the light source, and projects at least a part of the light beam onto the light irradiation object.

The present invention is directed to a driving method of an oscillation system of a oscillating member device having an oscillation system constituted of a oscillating member and an elastic support, and a driver unit for applying a driving force to the oscillation system in accordance with a driving signal, comprising steps of: controlling an amplitude control level based on an error instruction level obtained by multiplying the difference between a target oscillating amplitude and a oscillating amplitude to be detected of the oscillating member by the gain and practicing a control loop for producing a driving signal based on the controlled amplitude control level and a periodic signal of a prescribed frequency, and adjusting the gain of the control loop based on the amplitude control level in the state that the oscillating amplitude of the oscillating member is nearly equal to the target oscillating amplitude.

According to the present invention, the gain of the control loop is adjusted as mentioned above. Thereby the control loop gain is suitably set by the same control unit to drive the oscillation system stably even when the driving sensitivities are different greatly.

Further features of the present invention will become apparent from the following description of exemplary embodiments with reference to the attached drawings.

### BRIEF DESCRIPTION OF THE DRAWINGS

FIG. 1 illustrates the constitution of the light deflection apparatus of First Embodiment of the present invention.

FIG. 2 is a drawing for describing the deflection angle of the scanning light beam of the light deflection apparatus of First Embodiment.

FIG. 3 is a drawing for describing the change with time of the deflection angle of the light deflection apparatus.

FIG. 4 is a flow chart of the operation of the light deflection apparatus of First Embodiment.

FIG. 5 is a graph of dependency of the set gain on the amplitude control level with the light deflection apparatus of First Embodiment.

FIG. 6 illustrates the constitution of the light deflection apparatus of Second Embodiment of the present invention.

FIG. 7 is a flow chart of the operation of the light deflection apparatus of Second Embodiment.

FIG. 8 illustrates the constitution of the light deflection apparatus of Third Embodiment of the present invention.

FIG. 9 illustrates the constitution of the light deflection apparatus of Third Embodiment of the present invention.

FIG. 10 illustrates the constitution of the light deflection apparatus of Fourth Embodiment of the present invention.

FIG. 11 is a drawing for describing the deflection angle of the scanning light beam of the light deflection apparatus in Fourth Embodiment.

### DESCRIPTION OF THE EMBODIMENTS

Preferred embodiments of the present invention will now be described in detail in accordance with the accompanying drawings. In the oscillating member device and the driving method of the present invention, it is important that, in the control loop for controlling the level of the amplitude based on the difference between the target oscillating amplitude and the detected oscillating amplitude and the gain thereof, the gain is adjusted based on the amplitude control value in a state in which the oscillating amplitude of the oscillating member becomes equal to the target oscillating amplitude.

In this description, the wording “the state in which the oscillating amplitude of the oscillating member becomes equal to the target oscillating amplitude” includes the state of the oscillating amplitude practically equal to the target oscillating amplitude. In the present invention, the oscillating amplitude practically equal to the target oscillating amplitude may be defined suitably in a range in accordance with the specification of the employed oscillating member device. For example, the range may be defined within ±10% of the target amplitude.

Accordingly, a basic embodiment of the oscillating member device of the present invention comprises an oscillation system, a driver unit, a waveform-generator, a driving signal generator, and a oscillating amplitude detector. The oscillation system comprises a oscillating member and an elastic support. The driver unit supplies a driving force to the oscillation system according to a driving signal. The waveform generator generates periodic signals at a prescribed frequency. The driving signal generator generates driving signals in accordance with the periodic signals and the amplitude control level. The oscillating amplitude detector detects the oscillating amplitude of the oscillating member. The control loop operation is practiced for adjusting the amplitude control on the basis of the difference between the target oscillating amplitude and the oscillating amplitude detected by the oscillating amplitude detector, and the gain thereof. For example, the difference between the target oscillating amplitude and the detected oscillating amplitude of the oscillating member is multiplied by the gain to obtain an error instruction level, and based on this error instruction, the amplitude control level is adjusted. The oscillating member device comprises further a gain adjuster which sets the gain of the gain adjuster according to the aforementioned amplitude control level in the state in which the oscillating amplitude of the oscillating member is substantially equal to the target oscillating amplitude.

In the above-mentioned basic constitution in a state of practicing the control loop, for example, when the difference between the target oscillating amplitude and the detected oscillating amplitude detected by a oscillating amplitude detector comes to be within the predetermined range, the gain is set in the gain adjuster based on the amplitude control level.

The device may have a constitution, as in First Embodiment described later, in which a control level memory is provided for memorizing the amplitude control level; an amplitude control level in the state in which the oscillating amplitude of the oscillating member becomes equal to the target oscillating amplitude is memorized in a control level memory at a first timing; and the gain is set in the gain adjuster according to the amplitude control level stored in the control level memory at a second timing. In the present invention, the term “timing” signifies “a time or a time length for conducting the respective treatment”.

Otherwise the device may have another constitution, as in Second Embodiment described later, in which a gain memory is provided for memorizing the gain to be set in the gain adjuster; a gain for the gain adjuster is derived according to the amplitude control level in the state that the oscillating amplitude of the oscillating member is approximately equal to the target oscillating amplitude, and the gain is memorized in a gain memory at a first timing; and the gain stored in the control level memory is set in the gain adjuster at a second timing.

Further the device may have a constitution, as in Third Embodiment described later, in which a filter is provided for suppressing high-range variation of the amplitude control level, and the gain is set in the gain adjuster successively in accordance with the output from the filter.

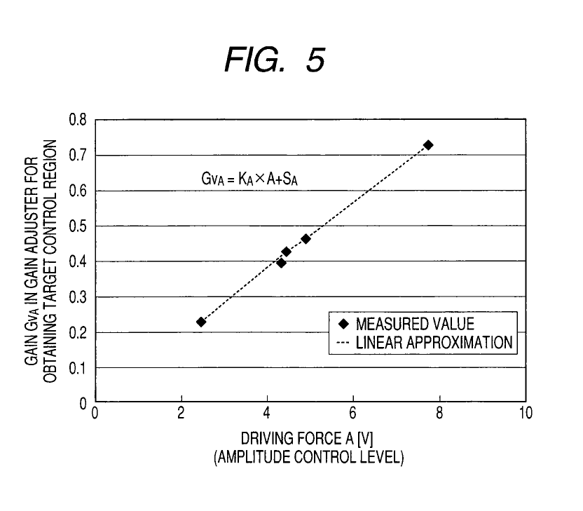

For example, from the amplitude control level necessary for obtaining the target oscillating amplitude and from the gain for the gain adjuster necessary for obtaining the target control region for the amplitude control levels, a conversion equation can be defined for converting the amplitude control level to the gain to be set in the gain adjuster. That is, as is described with reference to FIG. 5, a conversion equation can be defined from the sensitivity of the oscillating amplitude of the oscillating member to the amplitude control level, and the target control region of the control loop.

Further, the device may have still another constitution as in Fourth Embodiment described later. In the device, the oscillation system has a plurality of oscillating members and a plurality of elastic supports. The resonance frequencies include a primary resonance frequency and a secondary resonance frequency of n-times the primary resonance frequency (n: an integer of 2 or more). The waveform generator outputs a fundamental periodic signal of the set frequency and an n-th wave periodic signal of n-times the frequency of the set frequency. The driving signal generator generates the fundamental wave driving signal based on the fundamental wave periodic signal and the fundamental wave amplitude control level, and generates also an n-th wave driving signal based on the n-th periodic signal and n-th wave amplitude control level. The driver unit gives a driving force to the oscillation system based on the fundamental wave driving signal and the n-th wave driving signal. The oscillating amplitude detector detects oscillating amplitudes of the oscillation system corresponding to the fundamental wave driving signal and/or the n-th wave driving signal. The loop of the control of the fundamental wave amplitude control level and/or the n-th wave amplitude control level is practiced based on the difference of the target oscillating amplitude and the detected oscillating amplitude detected by the oscillating amplitude detector. The gain adjuster adjusts the gain of the fundamental wave driving signal of the oscillation system and/or the n-th wave driving signal thereof. Further, the fundamental wave control loop gain and/or the n-th wave control loop gain are set in the gain adjuster based on the fundamental wave amplitude gain level and/or the n-th wave amplitude control level in the state that the fundamental wave driving signal and/or the n-th wave control signal are nearly equal to the target oscillating amplitude.

The basic driving method of the oscillation system of the present invention which has an oscillation system constituted of a oscillating member and an elastic support, and a driver unit for applying a driving force to the oscillation system in accordance with a driving signal, further comprises steps below. In the first step, the amplitude control level is controlled based on the error instruction obtained from the difference between the target oscillating amplitude and the detected oscillating amplitude of the oscillating member multiplied by the gain, and the control loop for generating driving signal is practiced based on the controlled amplitude level and the periodic signal of the set frequency. In the second step, the gain of the control loop is adjusted based on the amplitude control level in the state that the oscillating amplitude of the oscillating member is nearly equal to the target oscillating amplitude.

A light deflection apparatus can be constituted by employing a oscillating member device, placing an optical deflection element in at least one oscillating member for deflecting a light beam introduced to the optical deflection element.

An optical instrument can be constituted by employing the light deflection apparatus, a light source, and a light irradiation object for projecting at least a part of the light beam emitted from the light source and deflected by the light deflection element onto the light irradiation object. An image-forming apparatus as an example of the optical instrument forms an electrostatic latent image by deflecting the light beam by the light beam deflection element and at least projecting a part of the light beam on a photosensitive member as the light irradiation object.

According to the present invention, even with a great difference in the driving sensitivity, an oscillation system can be driven stably by setting suitably the control gain by one and the same control assembly. Thus even with a great difference in the driving sensitivity, the control loop gain can be set within a target control region. Therefore the undesired accident can be avoided in which the oscillation system is not suitably driven and cause undesired high frequency oscillation. The term “high frequency oscillation” herein signifies uncontrollable continuation of amplification of high frequency oscillation. In a oscillating member device of MEMS scanner, for example, the undesired amplification of the high frequency oscillation can destroy a part of the MEMS scanner (e.g., a torsion spring).

The embodiments of the present invention are described specifically with reference to drawings.

### First Embodiment

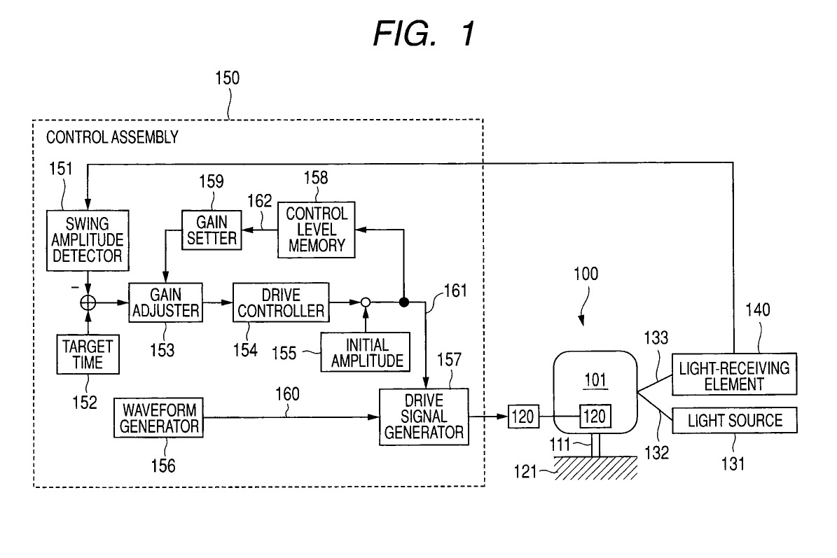

FIG. 1 illustrates a constitution of First Embodiment in which the present invention is applied to a light-beam deflection apparatus. In this Embodiment, the light beam deflection unit (optical scanner) comprises oscillation system 100 having one oscillating member 101 and torsion spring 111 as the elastic support; and supporting base 121 for supporting oscillation system 100. Driver unit 120 applies a driving force to oscillation system 100 on receiving a driving signal by an electromagnetic system, an electrostatic system, a piezo system, or the like. In electromagnetic driving, for example, a permanent magnet is attached to the oscillating member, and a coil for applying a magnetic field to this permanent magnet is placed near the oscillating member. Otherwise, the permanent magnet and the coil are placed reversely. In electrostatic driving, an electrode is attached to the oscillating member, and an opposite electrode for applying electrostatic force is placed near the oscillating member. In piezo electric driving, a piezo element is placed in the oscillation system or the fixing support to supply the driving force.

Oscillating member 101 has a light beam deflection element like a reflection mirror, reflects and deflects light beam 132 from light source 131 for scanning. Scanning light beam 133 passes twice over light receiving element 140 as the detecting means in one scanning cycle period. Control assembly 150 generates driving signals in accordance with the time at which scanning light beam 133 passes light receiving element 140, and sends the driving signal to driver unit 120.

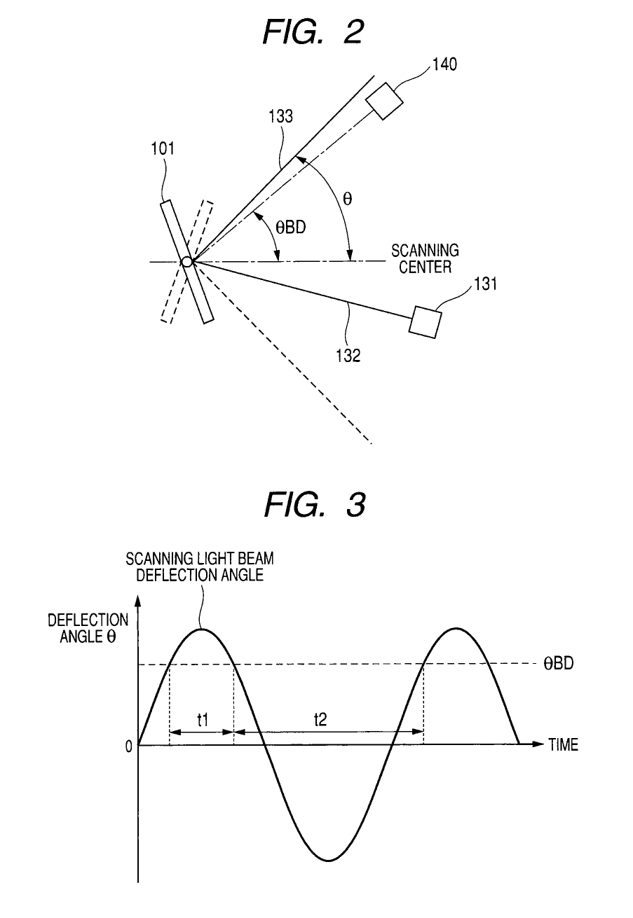

FIG. 2 illustrates an angle of deflection of scanning light beam 133 caused by oscillating member 101 in the light deflection apparatus. Light-receiving element 140 of the optical scanner is placed to receive light beam 133 at a position at a deflection angle (a setting angle θ BD) less than the maximum deflection angle of the optical scanner from the center of the scanning. In FIG. 2, light-receiving element 140 is placed in the light beam scanning path. Otherwise, light-receiving element 140 may be placed in the path of a scanning light beam deflected by an additional reflection mirror, or the like.

The constitution and operation of control assembly 150 illustrated in FIG. 1 is described below in detail. Oscillating amplitude detector 151 receives the output signal from light-receiving element 140 and measures the time intervals t1 and t2 of detection of scanning light beam 133. FIG. 3 shows a change with time of deflection angle θ of scanning light beam 133, and the time intervals t1 and t2 of passing the position of light-receiving element 140 placed at the set angle θBD of light-receiving element 140. Of the time intervals t1 and t2, the time interval shorter than a half period of the driving signal is identified as t1, and the other as t2. Thus, the time interval t1 corresponds to the oscillating amplitude of oscillating member 101. Therefore, in this specification, the target time interval and the oscillating amplitude are regarded as being equivalent. The change with time of the deflection angle θ of scanning light beam 133 corresponds to the oscillation state of the oscillating member 101 at a certain frequency.

Gain adjuster 153 derives an error instruction by multiplying the predetermined gain Gv by the difference Δt1 of the time intervals between target time 152 of detection at the target oscillating amplification and detected time interval t1. The gain adjuster outputs the error instruction signal to drive controller 154. Drive controller 154 controls the amplitude correction level based on the error instruction. On the other hand, waveform generator 156 generates predetermined periodic signal 160. Driving signal generator 157 generates driving signals based on the amplitude control level 161 (a sum of the amplitude correction and initial amplitude 155) and the periodic signal 160, and transmits the driving signal to driver unit 120. Typically, driving signals are generated which have amplitude proportional to amplitude control level 161 and proportional to the period of periodic signals 160. One amplitude and one frequency (period) of the driving signal can be decided according to the output from oscillating amplitude detector 151. Thus the detecting means is constituted simply one light-receiving element 140 for measuring of the time intervals of t1 and t2.

Control level memory 158 memorizes amplitude control level 161 of a predetermined scanning, and outputs the average of the memorized amplitude control levels 162. Gain setter 159 sets the gain Gv_{A} of gain adjuster 153 based on the memorized amplitude control level 162.

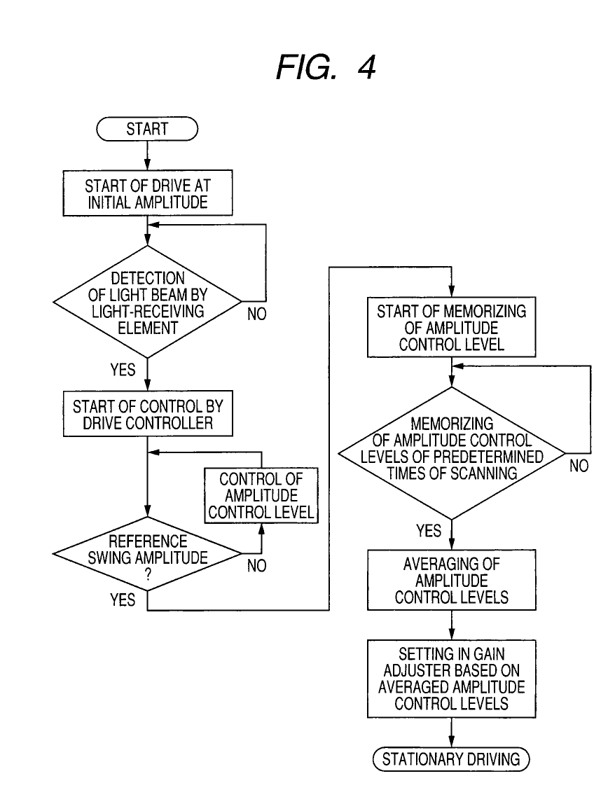

FIG. 4 shows a flow of the setting of the gain of the control loop in this Embodiment. The operation of setting the gain of the control loop before the stationary operation steps are described with reference to this flow chart. The driving is started by a driving signal derived from initial amplitude level 155 and periodic signal 160 emitted from waveform generator 156. The initial amplitude level 155 is decided within the range in which scanning light beam 133 is detectable by light-receiving element 140. The frequency set in waveform generator 156 is decided, for example, based on the resonance frequency in the production process, or on the driving frequency at the previous driving without change or with adjustment in consideration of the temperature (generally the resonance frequency is lower at a higher temperature). This frequency setting may be conducted automatically or manually by a user.

Drive controller 154 starts the drive control on detection of scanning light (light beam) 133 by the light receiving element 140 and receiving the error instruction. To prevent premature oscillation, the gain Gᵥ of gain adjuster 153 is preferably set to be lower than the optimum gain, for example to be about half of the optimum gain.

Control memory 158 starts to memorize amplitude control level 161 when the difference between the target oscillating amplitude (target time interval) and the oscillating amplitude (detected time interval) detected by oscillating amplitude detector 151 comes in a prescribed control range. The allowable difference may be, for example, about ±1%. Control level memory 158, which has memorized amplitude control level 161 for prescribed scanning cycles, outputs the average 162 thereof to gain setter 159. The number of the memorized scanning cycles is preferably in the range 50 to 200 cycles, but need not be average of the amplitude control levels of a plurality of amplitude control levels. An amplitude control level of one scanning cycle may be memorized and output.

In this Embodiment, gain setter 159 which has received the amplitude control level A from control level memory 158, derives the gain Gv_{A} from the amplitude control level A according to Equation (1) below, and set the derived gain in gain adjuster 153:

Gv_{A}=K_{A}×A+Sₙ (1)

The coefficient K_{A} and the intercept S_{A} in Equation (1) can be derived preliminarily from measurements with several light deflection apparatus having different driving sensitivity. Specifically, as illustrated in FIG. 5, with several light deflection apparatuses having different driving sensitivity, the amplitude control level A for obtaining the target oscillating amplitude and the gain of gain adjuster 153 for obtaining the target control region in the amplitude control level are measured for the respective apparatuses. From the measurement results, an approximate straight line represented by the broken line is obtained. This approximate line corresponds to the above Equation (1).

In this Embodiment, the approximate equation is derived by actual measurement, but is not limited thereto. The approximate equation may be derived by simulation. Further, in this Embodiment, Equation (1) is a linear function, but is not limited thereto, and may be of an n-order function or other multinomial expression. Otherwise, the gain Gv_{A} of gain adjuster 153 may be set with reference to a table which is equivalent to the above equations.

As described above, this embodiment employs a gain adjuster 153 for adjusting the gain in the control loop. Thereby amplitude control level 161 is memorized in the state in which the difference between the target oscillating amplitude and the amplitude detected by amplitude detector 151 is within a predetermined range. Thereby gain setter 159 sets the gain in gain adjuster 153 based on the memorized amplitudes control level 162.

In this Embodiment, the oscillating amplitude of oscillating member 101 is detected by scanning light beam 133 and light-receiving element 140. However, the oscillating amplitude may be detected by any detector capable of detecting the oscillating amplitude, such as a piezo-electric element. For example, the oscillating amplitude of oscillating member 101 may be detected by a piezo sensor provided on elastic support 111, by an electrostatic capacitor, or by a magnetic sensor.

In this Embodiment, the gain of the control loop is adjusted once at the start of the driving, but is not limited thereto. The gain may be adjusted, for example, during image formation, or an interim between image formation processes with an image-forming apparatus.

In this Embodiment, since the gain can be adjusted as described above, the control loop gain can be set suitably by the same one control assembly to realize stable drive of an oscillation system, even when the driving sensitivity varies greatly. Thus the control loop gain can be set within a target control band region even with great variation of the driving sensitivity.

### Second Embodiment

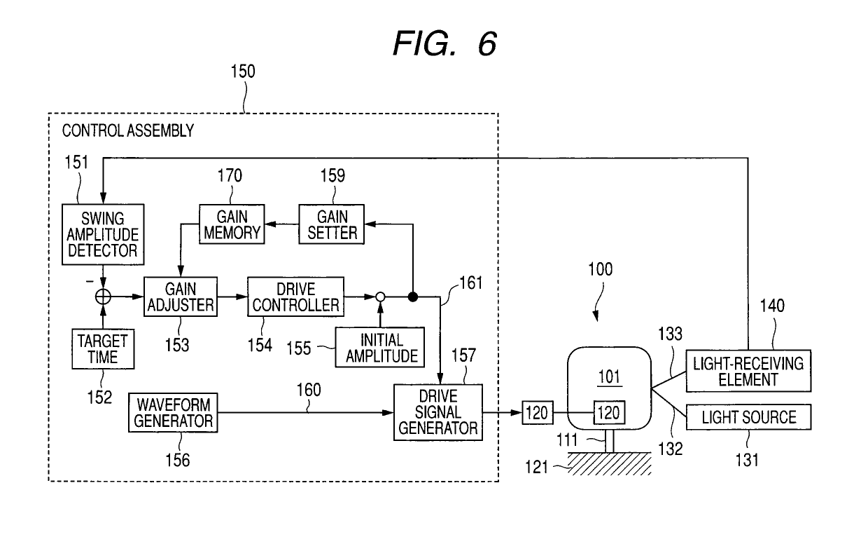

FIG. 6 illustrates a constitution of Second Embodiment of the present invention employed in a light deflection apparatus. In the light deflection apparatus of this Embodiment, the change of the deflection angle of scanning light beam 133, detection of the oscillating amplitude by light-receiving element 140 and oscillating amplitude detector 151, and operation drive controller 154 are similar to those described in First Embodiment. This Second Embodiment is different from First Embodiment in the constitution for setting of the gain in gain adjuster 153 as below. In First Embodiment, the gain is set in gain adjuster 153 based on the amplitude control level stored in control level memory 158 in a state that the difference between the target oscillating amplitude and the oscillating amplitude detected by oscillating amplitude detector 151 comes to fall in a predetermined range. On the other hand, in this Embodiment, the gain in gain adjuster 153 is derived by gain setter 159 based on amplitude level 161, and the gain is stored in gain memory 170, and the stored gain is set in gain adjuster 153.

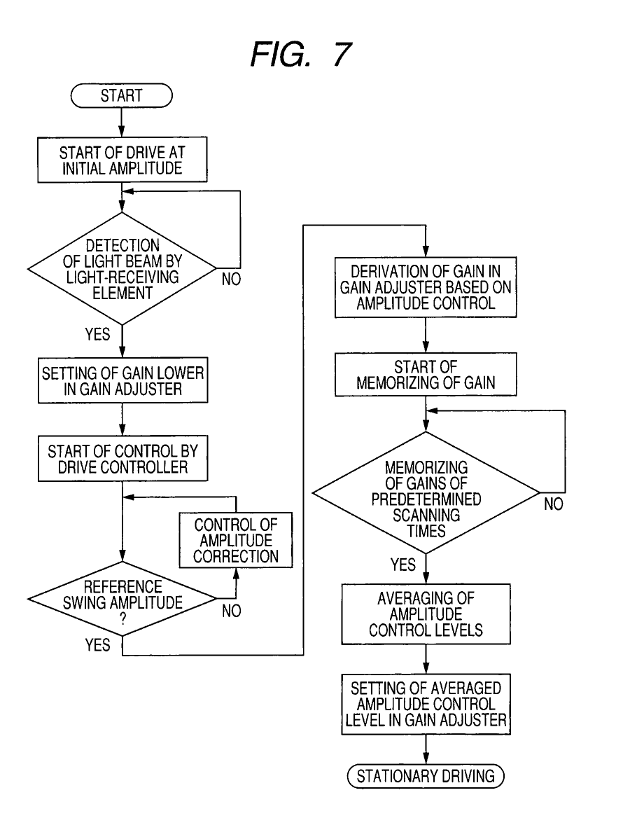

FIG. 7 shows a flow of the setting of the gain of the control loop in this Embodiment. The operation of setting the gain of the control loop before the stationary operation steps is described with reference to this flow chart. The driving is started by inputting a driving signal derived from initial amplitude level 155 and periodic signal 160 emitted from waveform generator 156. The initial amplitude level 155 is decided within the range in which scanning light beam 133 is detectable by light-receiving element 140. The frequency to be set in waveform-generator 156 is decided depending on the resonance frequency in the production process or a driving frequency in the previous driving. Drive controller 154 starts drive control on detection of scanning light (light beam) 133 by the light receiving element 140 and receiving the error instruction. To prevent premature oscillation, the gain Gᵥ of gain adjuster 153 is preferably set to be lower than the optimum gain.

For gain setter 159, gain Gv_{A} is derived from amplitude control level 161 according to the aforementioned Equation (1). Gain memory 170 starts to memorize gain Gv, when the difference between the target oscillating amplitude and the amplitude detected by amplitude detector 151 comes to fall within a predetermined range. Gain memory 170, after memorizing the gain Gv_{A} for the intended scanning, inputs the average of the gain in gain adjuster 153. The input gain need not be an average of the amplitude control levels of a plurality of amplitude control level. An amplitude control level of one scanning cycle may be memorized and output.

In this Embodiment also, similarly as in First Embodiment, the gain Gv_{A} can be derived not only by the above Equation (1) but may be derived by another approximate equation or a polynomial equation, or from a table equivalent to the equations.

As described above, in this Embodiment, gain adjuster 153 is employed for adjusting the gain in the control loop. The gain for gain adjuster 153 is derived from amplitude control level 161 in the state that the difference between the target oscillating amplitude and the detected oscillating amplitude detected by oscillating amplitude detector 151 is kept within a prescribed range. The derived gain is stored in gain memory 170, and the gain of gain adjuster 153 is set. Otherwise this Embodiment is the same as First Embodiment.

### Third Embodiment

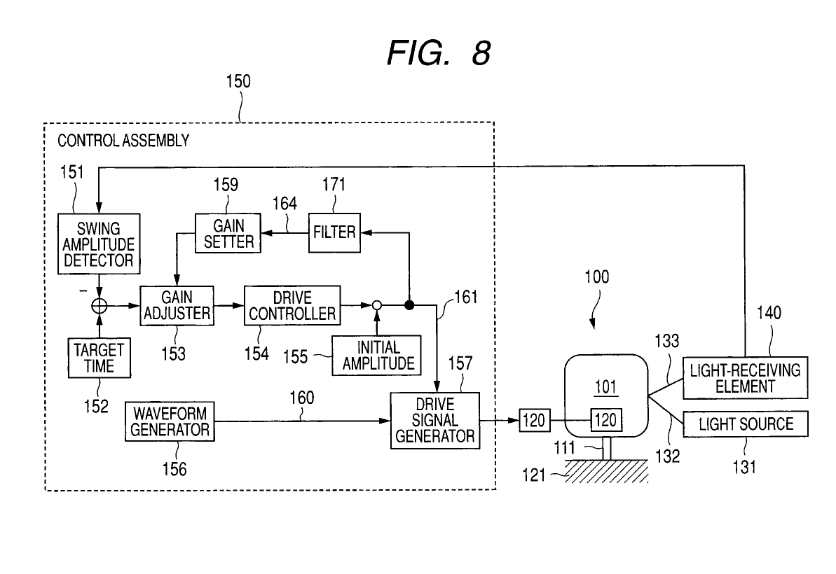

FIG. 8 illustrates a constitution of Third Embodiment of the present invention employed in a light deflection apparatus. In the light deflection apparatus of this Embodiment, the change of the deflection angle of scanning light beam 133, detection of the oscillating amplitude by light-receiving element 140 and oscillating amplitude detector 151, and operation of drive controller 154 are similar to those described in First Embodiment. This Third Embodiment is different from First Embodiment in setting of the gain in gain adjuster 153 as below. In First Embodiment, the gain is set in gain adjuster 153 based on amplitude control level 162 memorized in control level memory 158. On the other hand, in this Embodiment, the gain Gv_{A} is set in gain adjuster 153 based on filter output 164 from filter 171 for suppressing a high-region variation of amplitude control level 161.

The operation of setting of the gain in the control loop in this Embodiment is described below. The driving is started by a driving signal based on initial amplitude level 155 and periodic signal 160 from waveform generator 156. Initial amplitude level 155 is set so that scanning light beam 133 can be detected by light-receiving element 140. The frequency to be set in waveform generator 156 is selected based on the resonance frequency during production, and driving frequency in the preceding driving, and so forth. Drive controller 154 controls the driving when scanning light beam 133 is detected by light-receiving element 140 and the error instruction is obtained. In this Embodiment also, the gain Gv in gain adjuster 153 is set lower to prevent undesired premature oscillation.

When the difference between the target oscillating amplitude and the detected oscillating amplitude detected by the awing amplitude detector 151 comes to be within the predetermined range, filter 171 starts suppression of high-range variation of amplitude control level 161 to pass filter output 164 excluding the high-range variation of the amplitude control level. For obtaining stable filter output 164, the cutoff frequency of filter 171 is preferably not more than 1/10 of the set frequency in waveform-generator 156. Gain setter 159 derives gain Gv_{A} from filter output 164 of filter 171 according to the above Equation (1), and sets the gain in gain adjuster 153.

In this Embodiment also, similarly as in First Embodiment, the gain Gv_{A} can be derived not only by the above Equation (1) but may be derived by another approximate equation or a polynomial equation, or from a table equivalent to the equations.

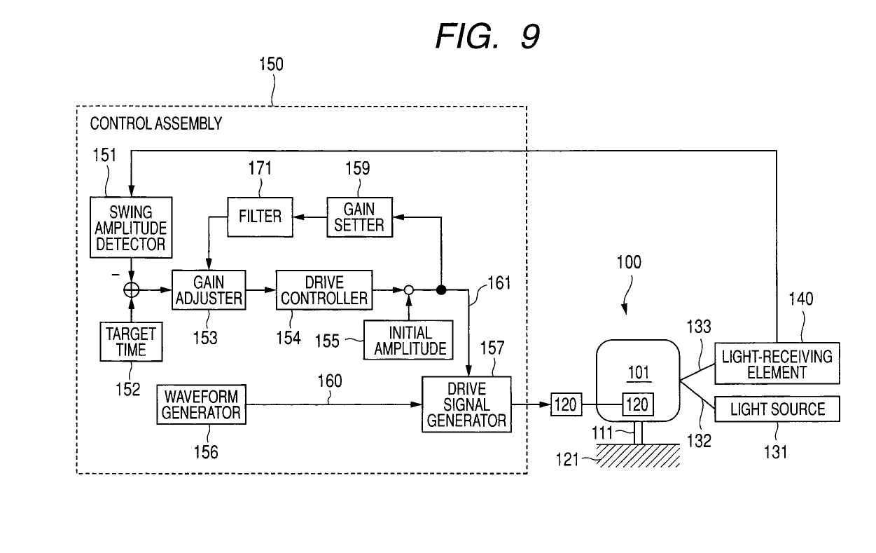

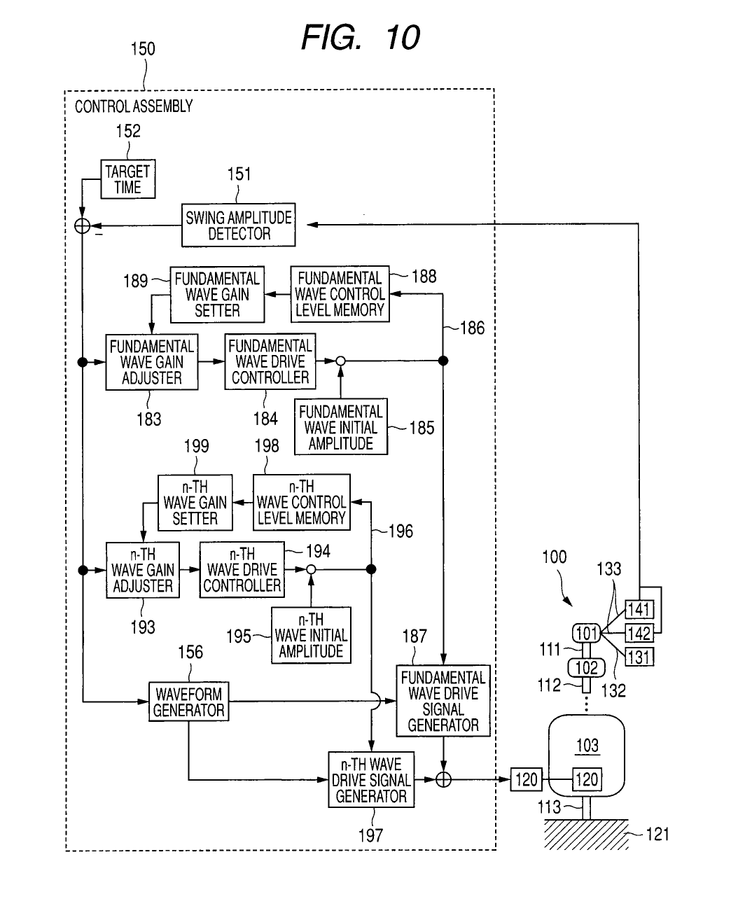

In this Embodiment, the amplitude control level after suppression of high-range variation by filter 171 is input to gain setter 159. This constitution may be modified as shown in FIG. 9 such that the high-range variation of the gain set by gain setter 159 according to amplitude control level 161 is suppressed by filter 171, otherwise being the same as in First Embodiment.

### Fourth Embodiment

FIG. 10 illustrates a constitution of Fourth Embodiment of the present invention employed in a light deflection apparatus. In this Embodiment, light beam deflector (optical scanner) comprises oscillation system 100 having, at least, first oscillating member 101, second oscillating member 102, first torsion spring 111, and second torsion spring 112; and supporting base 121 for supporting oscillation system 100. First torsion spring 111 as the elastic support connects first oscillating member 101 with second oscillating member 102. Second torsion spring 112 as the elastic support is connected to second oscillating member 102 to on the common torsion axis with first torsion spring 111. Oscillation system 100 of this Embodiment has at least two oscillating members and two torsion springs. The oscillation system may have three or more oscillating members 101, 102, 103; and three or more torsion springs 111, 112, 113 as illustrated in FIG. 10.

In this Embodiment, first oscillating member 101 has a reflection mirror on the surface thereof, allowing light beam 132 from light source 131 to scan. The function of driver unit 120 and the operation of control assembly 150 are basically the same as in First embodiment. This Embodiment is different from First Embodiment in that drive controllers 184, 194; initial amplitude levels 185, 195; gain adjusters 183, 193; control level memories 188, 198; and gain setters 189, 199 are respectively provided in the control loops for the fundamental wave and the n-th wave in control assembly 150, and is different also in that, target times 152 are provided for the first oscillation movement of first oscillating member 101 and the second oscillation movement of first oscillating member 101 excited by the n-th wave. Thereby, from the detected times measured by light-receiving elements 141, 142, oscillating amplitude detector 151 detects the times for oscillating amplitudes corresponding to the first and second oscillation movements excited by the basic wave and n-th wave. Thus, gain adjusters 183, 193 output the error instructions derived respectively by multiplying the installed gain by the difference between the detected time and the target time to drive controllers 184, 194 for the fundamental wave and n-th wave. Thereafter, the control operations for the first and second oscillation movements are conducted respectively in the same manner as in First Embodiment. Further, in this Embodiment, waveform generator 156 adjusts the phase difference between the periodic signals of the basic wave and the n-th wave to allow the scanning light beam to scan a predetermined orbital based on the difference relating to the basic wave and the n-th wave.

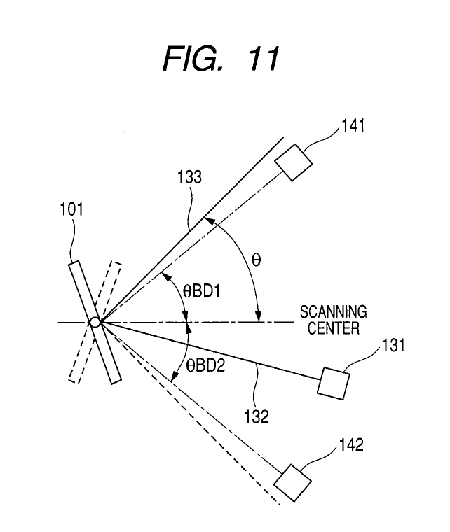

FIG. 11 illustrates the deflection angle of scanning light beam 133 caused by the reflection mirror of first oscillating member 101 of the light deflection apparatus of this Embodiment. The optical scanner has first and second light-receiving elements 141,142, placed respectively for receiving scanning light beam 133 at a deflection angle less than the maximum deflection angle of the light scanner (at positions of placement angles of θBD1 and θBD2). In FIG. 11, first and second light-receiving element 141, 142 are placed in the optical path of the optical scanner. Otherwise, first and second light-receiving elements 141, 142 may be placed on optical path of the light beam deflected further by an additionally provided reflection mirror or the like. In this Embodiment, for determining the two amplitudes and two phase differences of the basic wave and the n-th wave according to the output of oscillating amplitude detector 151, two light-receiving elements 141, 142 are provided to measure a larger numbers of detection times than that derived in First Embodiment.

In this Embodiment, oscillation system 100 has a constitution capable of causing simultaneously a first oscillation movement excited by a fundamental wave of fundamental frequency and a second oscillation movement excited by an n-th wave having an integral multiple of the fundamental frequency. Thus, the deflection angle θ of scanning light beam 133 of the light deflection apparatus of this Embodiment is represented as a function of the amplitude B₁, the frequency (angle frequency) ω₁, and the phase φ₁ of the first oscillation movement; and the amplitude B₂, the frequency (angle frequency) ω₂, and the phase φ₂ of the second oscillation movement; and the time t from a suitable original or reference time by Equation (2) below. The oscillation state of first oscillating member 101 and deflection angle θ of scanning light beam 133 are in one-to-one correspondence. Therefore, the oscillation state of first oscillating member 101 is represented substantially by this equation. Incidentally, in this Embodiment, the term “nearly integral multiple” signifies that the following relation is satisfied, when the resonance frequency of the fundamental wave is f₁ (=ω₁/2π) and the resonance frequency of the n-th wave is f₂ (=ω₂/2π): 0.98N≦f₂/f₁≦1.02N (N is an integer of 2 or more).

θ(t)=B₁ sin(ω₁t+φ₁)+B₂ sin(ω₂t+φ₂) (2)

To realize such an oscillation state of first oscillating member 101, the driving signal of the oscillating member device having two inherent oscillation modes of this Embodiment drives the oscillation system 100 in the oscillation state of first oscillating member 101 as represented by the above equation containing two sine-wave terms. This driving signal is not limited insofar as the signal allows first oscillating member 101 to oscillating in such an oscillation state. For example, the signal may be a driving signal synthesized from the fundamental wave and n-th sine wave, or may be a pulse driving signal. The desired driving signal can be obtained by adjusting the amplitudes and phases of the sine waves. In the driving by a pulsed signal, a desired driving signal can be obtained by changing the pulse number, pulse interval, the pulse width, and so forth with time by treating the synthesized sine waves by a predetermined conversion principle. For the driving signals, selection of the driving frequency of the fundamental wave of the driving signal decides the n-th wave driving frequency can be decided automatically from the driving frequency of the fundamental frequency by multiplication by the factor n. Therefore, first and second light-receiving elements 141, 142 are placed for deciding the two amplitudes and phase difference of driving signals.

The operation for setting the gain of the control loop in this Embodiment is described below. The driving is started by a driving signal according to fundamental initial amplitude 185, n-th wave initial amplitude 195, and the fundamental-wave periodic signal and n-th wave periodic signal emitted from waveform-generator 156. The driving signal is a synthesis product obtained from the fundamental wave, and components generated by n-th wave driving signal generators 187, 197.

When scanning light beam 133 is detected by light-receiving elements 141, 142, and a fundamental wave error instruction and an n-th wave error instruction are obtained, fundamental wave drive controller 184 and n-th wave drive controller 194 controls the drive, in the same manner as in First Embodiment. When the difference between the target oscillating amplitude of the first or second oscillation and the detected oscillating amplitude of the first or second oscillation derived by the oscillating amplitude detector comes within a prescribed range, control level memory 188,198 for the fundamental wave or n-th wave starts the memorization of the amplitude control level of the fundamental wave or the n-th wave. The control level memories 188, 198, after amplitude control levels 186,196 of the fundamental wave or the n-th wave, input the averages of the levels to gain setters 189, 199 for the fundamental wave or the n-th wave. The averaging of the amplitude control levels is not essential similarly as in First Embodiment.

Fundamental wave gain setter 189 derives the fundamental wave gain Gv_{B1} from the fundamental wave amplitude control level B₁ emitted form fundamental wave control level memory 188 according to Equation (3) below, and set it as the gain in fundamental wave gain adjuster 183. n-Th wave gain setter 199 derives n-th wave gain Gv_{B2} from the n-th wave amplitude control level B₂ emitted from n-th wave control level memory 198 according to Equation (4) below and set it as the gain in n-th gain adjuster 193.

Gv_{B1}=K_{B1}×B₁+S_{B1} (3)

Gv_{B2}=K_{B2}×B₂+S_{B2} (4)

The coefficients K_{B1} and K_{B2}, and the intercepts S_{B1} and S_{B2} in Equations (3) and (4) can be derived preliminarily from measurements with several light deflection apparatuses having different driving sensitivities similarly as in First Embodiment. In this Embodiment also, Equations (3) and (4) are respectively a linear function, but are not limited thereto, and may be of an n-order function or other polynomial expression. Otherwise, the fundamental wave gain Gv_{B1} of fundamental wave gain adjuster 183 and the n-th wave gain Gv_{B2} of fundamental wave gain adjuster 193 may be set with reference to a table which is equivalent to the above equations.

In the constitution of this Embodiment, both of the gains of fundamental wave gain adjuster 183 and n-th wave gain adjuster 193 are adjusted. However, the constitution may be designed for adjusting either one of the gains. For example, the gain is not adjusted for the oscillation movement of driving frequency approximate to the resonance frequency.

The level emitted from the gain adjuster based on the amplitude control level may be stored in the gain memory and may be set as the gain in the gain adjuster as in Second Embodiment. Or a filter may be employed as in Third Embodiment. Other parts of the constitution are the same as in First Embodiment.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2008-211608, filed on Aug. 20, 2009, which is hereby incorporated by reference herein in its entirety.

What is claimed is:

1. A oscillating member device comprising:
an oscillation system containing of a oscillating member and an elastic support,
a driver unit for supplying a driving force to the oscillation system according to a driving signal,
a waveform generator for generating periodic signals at a prescribed frequency,
a driving signal generator for generating the driving signals in accordance with the periodic signals and an amplitude control level, and
a oscillating amplitude detector for detecting a oscillating amplitude of the oscillating member; and practicing a control loop for controlling the amplitude control level according to a difference between a target oscillating amplitude and a detected oscillating amplitude detected by the oscillating amplitude detector, and the gain thereof;
the oscillating member device further comprising a gain adjuster for adjusting a gain of the control loop, and the gain of the gain adjuster being set based on the amplitude control level in a state that the oscillating amplitude of the oscillating member is equal to a target oscillating amplitude.

2. The oscillating member device according to claim 1, wherein, in practicing the control loop, the gain of the gain adjuster is set in accordance with the amplitude control level in a state that the difference between the target oscillating amplitude and the detected oscillating amplitude detected by the oscillating amplitude detector comes to be within a predetermined range.

3. The oscillating member device according to claim 1, wherein a control level memory is provided for memorizing the amplitude control level, the amplitude control level in the state in which the oscillating amplitude of the oscillating member becomes equal to the target oscillating amplitude is memorized in the control memory at a first timing, and the gain is set in the gain adjuster according to the amplitude control level stored in the control level memory at a second timing.

4. The oscillating member device according to claim 1, wherein a gain memory is provided for memorizing the gain to be set in the gain adjuster,
a gain for the gain adjuster is derived according to the amplitude control level in the state that the oscillating amplitude of the oscillating member is nearly equal to the target oscillating amplitude, and
the gain is memorized in a gain memory at a first timing; and the gain stored in the control level memory is set in the gain adjuster at a second timing.

5. The oscillating member device according to claim 1, wherein a filter is provided for suppressing high-range variation of the amplitude control level, and the gain is set in the gain adjuster successively in accordance with the output of the filter.

6. The oscillating member device according to claim 1, wherein a conversion equation which converts the amplitude control level to the gain to be set in the gain adjuster and necessary for obtaining the target oscillating amplitude is defined.

7. The oscillating member device according to claim 1 wherein the oscillation system has a plurality of oscillating members and a plurality of elastic supports; the resonance frequencies include a primary resonance frequency and a secondary resonance frequency of n-times the primary resonance frequency (n: an integer of 2 or more);
the waveform generator outputs a fundamental periodic signal of the prescribed frequency and an n-th wave periodic signal of n-times the frequency of the prescribed frequency;
driving signal the driving signal generator generates a fundamental wave driving signal based on the fundamental wave periodic signal and the fundamental wave amplitude control level, and generates also an n-th wave driving signal based on the n-th periodic signal and n-th wave amplitude control level;
the driver unit supplies a driving force to the oscillation system based on the fundamental wave driving signal and the n-th wave driving signal;
the oscillating amplitude detector detects oscillating amplitudes of the oscillation system corresponding to the fundamental wave driving signal and/or the n-th wave driving signal;
the control loop of the control of the fundamental wave amplitude control level and/or the n-th wave amplitude control level is practiced based on the difference of the target oscillating amplitude and the detected oscillating amplitude detected by the oscillating amplitude detector and the fundamental wave control loop gain and/or the n-th wave control loop gain;
the gain adjuster adjusts the fundamental wave control loop gain and/or the n-th wave control loop gain of the control loop; and
the fundamental wave control loop gain and/or the n-th wave control loop gain are set in the gain adjuster based on the fundamental wave amplitude control level and/or the n-th wave amplitude control level in the state that the oscillating amplitude corresponding to the fundamental wave driving signal and/or the n-th wave control signal is nearly equal to the target oscillating amplitude.

8. A light deflection apparatus employing the oscillating member device set forth in claim 1, having an optical deflection element placed in at least one oscillating member for deflecting a light beam introduced to the optical deflection element.

9. An optical instrument, employing the light deflection apparatus set forth in claim 8, a light source, and a light irradiation object, which deflects a light beam emitted from the light source, and projects at least a part of the light beam onto the light irradiation object.

10. A driving method of an oscillation system of a oscillating member device having an oscillation system constituted of a oscillating member and an elastic support, and a driver unit for applying a driving force to the oscillation system in accordance with a driving signal, comprising steps of:
controlling an amplitude control level based on an error instruction level obtained by multiplying the difference between a target oscillating amplitude and a oscillating amplitude to be detected of the oscillating member by the gain and practicing a control loop for producing a driving signal based on the controlled amplitude control level and a periodic signal of a prescribed frequency, and
adjusting the gain of the control loop based on the amplitude control level in the state that the oscillating amplitude of the oscillating member is nearly equal to the target oscillating amplitude.
